(19) United States
(12) Patent Application Publication
(10) Pub. No.: US 2025/0183789 A1
(43) Pub. Date: Jun. 5, 2025

(54) METHOD FOR DETERMINING THE STATE OF AN INVERTER

(71) Applicant: Baumueller Nuernberg GmbH, Nuernberg (DE)

(72) Inventor: Magdi DIMAS ZEKRI, Nuernberg (DE)

(73) Assignee: Baumueller Nuernberg GmbH, Nuernberg (DE)

(21) Appl. No.: 19/043,745

(22) Filed: Feb. 3, 2025

Related U.S. Application Data
(63) Continuation of application No. PCT/EP2023/070397, filed on Jul. 24, 2023.

(30) Foreign Application Priority Data
Aug. 3, 2022 (DE) 10 2022 208 056.4

(51) Int. Cl. H02M 1/32; H02H 7/122; H02M 7/5387

(52) U.S. Cl. CPC H02M 1/327; H02H 7/122; H02M 7/5387

(57) ABSTRACT

A method for determining a state of an inverter on the basis of a plurality of sensor values, each of which corresponds to a measured value created via an analogue sensor of a sensor unit. A clock signal, which has a plurality of identical clock pulses having two different clock states, is sent to each sensor unit. During one of the clock states of each clock pulse, a predefined reference value for each sensor unit is changed by the current measured value to an intermediate value by a predefined operation. During the other clock state of each identical clock pulse, the intermediate value for each sensor unit is changed by an auxiliary value up to the reference value by an opposite operation. During each remaining time span of said identical clock pulse, a first state and otherwise a second state is used as the relevant sensor value.

This nonprovisional application is a continuation of International Application No. PCT/EP2023/070397, which was filed on Jul. 24, 2023, and which claims priority to German Patent Application No. 10 2022 208 056.4, which was filed in Germany on Aug. 3, 2022, and which are both herein incorporated by reference.

### BACKGROUND OF THE INVENTION

### Field of the Invention

The invention relates to a method for determining the state of a converter, and a converter. The converter in each case may have multiple sensor units, each with an analog sensor.

### Description of the Background Art

Converters generally have multiple electrical and/or electronic components which heat up during operation due to electrical losses. When a critical temperature is exceeded, the individual components are damaged and must be replaced. To avoid this situation, multiple temperature sensors are generally present, and the converter is switched off when the temperature, reduced by a safety threshold, is reached.

It is becoming increasingly common for such converters to have individual modules, each of which includes one or more power semiconductor switches by means of which a comparatively high voltage, namely, the DC link voltage, is connected. Installation of the converter is facilitated on account of the modules. The control and/or regulation of the converter, via which the power semiconductor switches are also actuated, generally take(s) place by use of a control unit. The control unit of the converter is usually galvanically separated from the voltages that are connected by means of the power semiconductor switches, thus ensuring safe operation for persons. This also reduces requirements imposed on the components used for implementing the control unit.

A temperature sensor or at least a temperature-dependent resistor, by means of which the temperature of the module and thus also of the power semiconductor switches can be determined, is generally embedded in the modules. The resistor is generally not securely galvanically separated with respect to the voltages conducted by the particular module. For further processing of the electrical resistance provided in this way, or of a voltage resulting as a function of the resistance by means of the control unit, it is thus necessary to make a galvanic separation.

Since the resulting voltage or the resistance is an analog signal for each module, an analog galvanic separation is thus necessary, which, however, is comparatively costly. In an example, the particular value is digitized in each case by use of a delta-sigma modulator associated with the particular module, by means of which the signal created in this way is fed into an output line. A comparatively costly delta-sigma modulator is thus necessary for each module. The signals of the different modules are not synchronous with one another, for which reason at least four cores of the output line must be associated with each module, which increases cabling outlay and thus also manufacturing effort.

In another example, the resulting voltages or the particular resistance are/is transferred, via an individually associated line, to a shared digitization circuit by means of which the digitization and optionally also minor evaluation take place. The signals created by means of the digitization circuit are transferred to the controller via a galvanic separator, such as an optocoupler. The number of components for digitization and for galvanic separation are thus reduced. However, a comparatively large number of possibly long lines are necessary between the modules and the digitization circuit; these lines are not galvanically separated from the comparatively high DC link voltage, for which special requirements for contact protection thus exist. Complexity and manufacturing costs are thus increased.

### SUMMARY OF THE INVENTION

It is therefore an object of the invention to provide a particularly suitable method for determining the state of a converter, and a particularly suitable converter, wherein safety is advantageously enhanced and manufacturing costs are reduced, and further processing is advantageously facilitated.

The method is used to determine the state of a converter. The converter can be an inverter, a power converter, a rectifier, or a DC/DC converter, for example. The electrical power provided by the converter during operation is preferably between 200 W and 500 kW. The converter is, for example, an integral part of an industrial facility and is used, for example, for operating an actuator via which a workpiece is produced and/or processed. Alternatively, the converter is used to supply power to an electric motor that drives a vehicle, for example a motor vehicle such as a passenger car, or a commercial vehicle such as a truck or bus. Alternatively, the vehicle is a snow groomer, a construction machine, or an agricultural implement.

In particular, the converter can have multiple power semiconductor switches, the state of the converter being determined in particular based on the state of the power semiconductor switches or being at least related thereto. The power semiconductor switches are preferably present in modules, for example with two power semiconductor switches always being combined to form such a module. In particular, a bridge circuit, preferably a B6 circuit, is provided by means of the power semiconductor switches. It is suitable for three modules to be present, with a bridge branch being provided by means of each module.

The converter can have multiple sensor units, each of which includes an analog sensor. For example, all sensors as well as the analog sensors have the same design. Alternatively, the sensor units are different, or at least differ with respect to the analog sensors. However, the same physical variable is particularly preferably measured in each case by means of the analog sensors. A corresponding analog sensor is suitably associated with each possible module, so that for a B6 circuit, preferably three sensors and thus three sensor units are present.

Each analog sensor can be a temperature sensor, which may be used to measure in particular a temperature of the particular module or some other component of the converter. The state of the converter to be determined preferably corresponds to a temperature of the converter, with the state corresponding to the temperature, for example, or the state having only two states, for example, such as operation at operating temperature (normal temperature range) and overheating of the converter. Each analog sensor preferably has a temperature-dependent resistor that is advantageously interconnected via further components in such a way that each analog sensor provides a voltage that is advantageously functionally related to the particular present resistance of the temperature-dependent resistor, and thus related to the temperature acting thereon. For example, the temperature and the voltage are directly proportional to one another, and a linear relationship exists between them. In particular, the voltage provided by means of the analog sensor is an analog signal having no different discrete stages. The analog sensor is advantageously optimized in such a way that it is comparatively/sufficiently accurate in a temperature range between 60° C. and 100° C.

In summary, during operation an analog measured value that is directly measured, for example, is created by means of the analog sensor. However, the analog sensor preferably already provides preprocessing via which, for example, a resistance that changes due to physical effects to be measured is transferred into an associated voltage. Alternatively or in combination therewith, amplification takes place, thus facilitating further processing. The value created in this way corresponds to the measured value that is provided by means of the particular analog sensor.

The method provides that initially a clock signal is sent to the sensor units. The clock signal is provided in particular by means of a clock generator, and comprises multiple identical clock pulses, which thus are not different, and which in each case advantageously follow one another in direct succession. Each clock pulse has two different clock states. For example, each clock pulse has just two different clock states, so that the clock signal is binary. For example, each clock pulse is uniformly distributed over the two clock states. However, it is particularly preferred for at least one of the clock states, preferably the later of the two clock states, to be temporally longer.

According to the method, during one of the clock states of each clock pulse, for each sensor unit a predefined reference value can be changed by the present measured value, provided by means of the particular analog sensor, to a respective intermediate value by means of a predefined operation. In other words, as long as one of the clock states continues, the predefined operation is carried out in succession, so that the initially predefined reference value is changed to the intermediate value. The reference value is, for example, the same for all sensor units, and for example is centrally predefined, or particularly preferably is predefined separately for each sensor unit, so that the reference values may differ among the individual sensor units, for example due to manufacturing tolerances. Manufacturing costs are thus reduced. In particular, the application of the operation takes place with a certain time constant, which advantageously is the same for all sensor units.

In summary, for each sensor unit, during the one clock state of each clock pulse the operation is thus applied repeatedly, so that the particular reference value can be successively changed based on the particular present measured value, which in each case is determined by means of the particular analog sensor. After the clock state expires, the intermediate values, which differ due to the different measured values between the individual sensor units, are present. However, since the clock signal is temporally predefined for all sensor units, the intermediate values of the different sensor units are reached in each case at the same point in time.

In a subsequent work step, during the other clock state of the same clock pulse, for each sensor unit the particular intermediate value can be changed by a respective auxiliary value to the reference value by means of an opposite operation. The opposite operation is, for example, the operation that is inverse to the operation by means of which the reference value has been changed to the intermediate value. When the reference value has been reached, the opposite operation is no longer carried out, and instead the reference value is not further changed; i.e., the intermediate value is not further changed. In particular, the auxiliary value is constant. The auxiliary value is externally predefined, for example, for all sensor units, or is advantageously created by each sensor unit itself; the auxiliary values preferably differ comparatively very little between individual sensor units. For each sensor unit, the auxiliary value is at least in a fixed ratio with the reference value, the components of the sensor unit in particular being such that the ratio preferably has only slight fluctuations among the individual sensor units. In particular, an interconnection of the sensor units and/or of the components used, on the basis of which the auxiliary value is predefined, has minor error tolerances, so that comparability of the sensor values to be created is increased among the sensor units.

The changing of the reference value to the intermediate value, and of the intermediate value to the reference value, take place in particular by use of analog technology. In other words, this takes place in the analog domain, and neither the auxiliary value, the intermediate value, nor the reference value is present as a digital signal.

After the reference value has been reached once again, during the particular remaining time period of the same clock pulse a first state is used as the particular sensor value. Otherwise, during the remaining time period of the same clock pulse a second state is used as the particular sensor value. In other words, the sensor value thus has only two different states, and the determination takes place by use of a comparator, for example. In summary, during each clock pulse, as long as the reference value is not present, the second state is thus used as sensor values, and otherwise the first state is used. Consequently, each sensor value is present as a binary signal. The different states advantageously correspond to different electrical potentials, so that further processing is simplified. Alternatively or in combination therewith, the reference value, the intermediate value, and/or the auxiliary value are different electrical potentials.

The sensor values created in this way are fed by means of a supply circuit, in particular immediately, i.e., during the particular clock pulse, into a shared output line that is directed toward an output point. In other words, the binary sensor values created in this way are fed into the output line, so that a binary signal is now present at the output point, which simplifies further processing. Each of the sensor values corresponds to a piece of information concerning the state of the converter, so that the state of the converter is determined by use of the method. The output point is in particular an integral part of a controller of the converter, via which, for example, regulation and/or control of delivered power take(s) place. In particular, the controller is suitable, in particular provided and configured, for operation by a human. By use of the controller, the state is advantageously further evaluated and/or (some other) operation of the converter is adapted on this basis.

In the method, for the different sensor units the shared clock signal is used, and it is necessary only for the auxiliary values for the different sensor units and/or their ratio to the reference value used in each case to differ only comparatively slightly. Thus, only components with relatively low manufacturing tolerances are necessary there. For the other components, comparatively large error tolerances may be selected without affecting the method. Manufacturing costs are thus reduced. Since the binary sensor values or signals based thereon are also fed into the output line by means of the supply circuit, further processing is simplified. Since the sensor values have only two different states, it is possible to select the electrical potentials, which represent the different states, to be comparatively low, thus enhancing safety.

For example, all sensor values are fed separately into the output line, in particular one core of the output line being associated with each sensor value. In other words, multiple values are present at the output point, each of which corresponds to one of the measured values. Evaluation and/or comparatively accurate determination of the present state of the converter are/is thus possible. Alternatively, for example only a limited number of cores are present, and the output line is operated in the manner of a bus system. Due to the predefined clock signal, which is the same for all sensor units, coordinated feeding of the different sensor values is possible, thus further reducing the manufacturing effort.

However, it is particularly preferred that only an extreme value of the sensor values is transferred to the output point. Further processing is thus simplified. In particular, the extreme value is used as the state of the converter, and/or the extreme value corresponds to a certain state of the converter, such as in particular overheating or operation in a normal temperature range. For example, the extreme value is the sensor value that is farthest from a predefined value. In particular, the extreme value is the minimum or the maximum of the sensor values. If the sensor values correspond to the present temperature, the extreme value preferably corresponds to the maximum.

In particular, for transferring only the extreme value, the supply circuits have a logic circuit that is used for performing appropriate feeding, for example coordinated in each case with the other sensor values. The sensor units are preferably interconnected to the output line via an “and” operation or an “or” operation. All sensor values are advantageously fed simultaneously into the output line, resulting in overlap of the sensor values. The feeding takes place in particular in such a way that due to the overlap, only the extreme value is tappable at the output point. In this way interconnection is further simplified, and the supply circuits may be produced comparatively inexpensively.

For example, the supply circuits are each designed in the manner of a Schmitt trigger. However, each supply circuit particularly preferably has a switching element that is actuated based on the particular sensor value. In other words, based on the particular sensor value the switching element of the particular sensor unit is actuated. The switching elements of all sensor units are electrically connected in parallel between a reference potential, whose value is that of ground, for example, and the output point. Since the sensor values are binary signals, either the reference potential or an electrical potential that differs therefrom is thus present at the output point. Due to such an interconnection, depending on the arrangement, the output point for the first state or the second state of the particular sensor value is thus directed toward the reference potential, wherein the temporal length thereof corresponds to the measured value/sensor value which represents the extreme value. In particular, the highest temperature that is measured by means of the analog sensor is derivable based on the time period for which the output point is directed toward the reference potential, and is in a functional relationship with same.

The particular sensor value can be transferred to the switching element with galvanic separation. In particular, an optocoupler is used for this purpose, and the switching element is, for example, an integral part of the optocoupler.

Consequently, the output point and also the output line are galvanically separated from the other voltages that are conducted via the particular sensor unit, and in particular from the analog sensor, thereby enhancing safety. It is also possible to position the particular analog sensor, for example, comparatively close to any power semiconductor switches, thus increasing measurement accuracy while still enhancing safety. In addition, requirements imposed on the output line are reduced due to the galvanic separation, so that comparatively inexpensive components may be used, thus further reducing manufacturing costs.

The clock signal can be received via a galvanic separator of the particular sensor unit. In other words, the clock signal is galvanically separated from the other components of the sensor unit by means of the galvanic separator of the particular sensor unit, in particular from the analog sensor. The clock signal is preferably provided by a clock generator which, for example, is an integral part of a controller of the converter. The design is simplified in this way. Due to the respective galvanic separator, it is possible to operate the controller at a separate electrical potential with regard to the sensor units or any of the modules associated with the sensor units, thus enhancing safety. In addition, there are less stringent requirements for the line for transferring the clock signal to the sensor units, thus reducing manufacturing costs.

For example, the line via which the clock signal is provided and the output line are implemented using a shared cable, the sensor values advantageously also being fed into the output line with galvanic separation, so that the particular sensor values are transferred to the particular switching element with galvanic separation. Safety is thus further enhanced and manufacturing costs are also reduced. In addition, it is possible to arrange the analog sensors comparatively far apart from any controller.

For example, each of the sensor units can have one or more voltage sources, the reference value being provided by one of the voltage sources, and the auxiliary value being provided by the other of the voltage sources, thus increasing flexibility. However, each sensor unit particularly preferably has only a single voltage source, on the basis of which the particular reference value and the particular auxiliary value are created, the reference value and the auxiliary value being provided by means of a shared voltage divider. In other words, the voltage divider is additionally present, which has multiple ohmic resistors electrically connected in series, between which a tap is formed in each case, with one of the taps being associated with the reference value and the other tap being associated with the auxiliary value. In the method, it is not the absolute values of the reference value and of the auxiliary value that are important, but, rather, their ratio to one another. In this refinement the ratio is predefined by means of the voltage divider and thus based on the ohmic resistors. Such ohmic resistors are comparatively inexpensive with low manufacturing tolerances, thus further reducing manufacturing costs. In other words, no separate voltage sources and/or capacitors are required.

Negative integration is particularly preferably used as the operation that changes the reference value to the intermediate value, and integration is used as the opposite operation. The same time constant is advantageously used for the negative integration and the integration. Alternatively, different time constants are assigned. This selection for the operation ensures that the reference value or the intermediate value is not changed excessively, so that no malfunction occurs. Within the one clock state the voltage, when it is used for the reference value and the measured value, drops comparatively quickly for a large measured value. In other words, the slope of the drop is a function of the particular measured value. In contrast, the drop from the particular intermediate value implemented in each case always takes place with the same slope, namely, by the auxiliary value, wherein as a function of the particular measured value/intermediate value that is implemented, the length of the time window until the reference value is again reached, and thus the length of the remaining time period, are a function of the particular measured value.

For the integration or negative integration, it is suitable to use an operational amplifier in each case which is appropriately connected. Use of these operations simplifies an interconnection of the sensor units, which can be implemented using comparatively inexpensive components. In addition, it is possible to connect the operational amplifier, by means of which the integration takes place, in such a way that a limitation to the reference value occurs, thus further simplifying an interconnection. In particular, the two operational amplifiers are suitably connected to one another.

The converter can include multiple sensor units, each having an analog sensor, and an output line that is directed toward an output point. The output line is preferably directed toward a controller of the converter, and the output point is advantageously an integral part of the controller. The electrical potential present at the output line is suitably queried by means of the controller. The converter is operated according to a method for determining the state of a converter. According to the method, a clock signal that has multiple identical clock pulses with two different clock states is sent to each sensor unit, and during one of the clock states of each clock pulse, for each sensor unit a predefined reference value is changed by the particular present measured value to a respective intermediate value by means of a predefined operation. During the other clock state of the respective same clock pulse, for each sensor unit the particular intermediate value is changed by a respective auxiliary value to the reference value by means of an opposite operation, and during the respective remaining time period of the same clock pulse a first state is used as the particular sensor value, and otherwise a second state is used. The sensor values are fed by means of a supply circuit into a shared, suitable output line that is directed toward an output point.

The sensor units can have the same design and/or are used in particular to determine a temperature. For this purpose, each analog sensor suitably has a temperature-dependent resistor that is connected by means of an operational amplifier, for example, in such a way that each analog sensor provides a voltage that is a function of the temperature acting on the temperature-dependent resistor. The converter, preferably the controller, has a clock generator that provides the clock signal during operation.

In particular, the converter can have multiple modules with which each of the analog sensors is associated. Each module advantageously has two power semiconductor switches electrically connected in series, so that they implement a bridge branch. The converter preferably includes a DC link that preferably conducts a direct voltage greater than 200 V during operation, with the modules being electrically connected in parallel between the two electrical potentials.

In particular, an operational amplifier can be used in each case for carrying out the operation and the opposite operation, using inverse integration, for example, as the operation. In particular, due to the interconnection of the two operational amplifiers a limitation to the reference value takes place, for which purpose a diode is preferably used which in particular connects the output of one of the operational amplifiers, referred to below as the first operational amplifier, to the inverting input of the remaining operational amplifier, referred to below as the second operational amplifier. The output of the operational amplifier is likewise directed toward its inverting input, preferably via a capacitor. In addition, the output of the operational amplifier is directed toward the non-inverting input of the first operational amplifier, by means of which the integration thus takes place, whereas the negative integration takes place with the second operational amplifier.

The invention further relates to a sensor unit for carrying out the method. In each case a portion of the method is carried out via the sensor unit.

The sensor unit includes an analog sensor that provides, for example, a voltage that is proportional to a physically implemented value. In particular, the analog sensor is suitable, and in particular provided and configured, for measuring a temperature. The analog sensor preferably includes a temperature-dependent resistor, which in particular is connected by means of an operational amplifier in such a way that the analog sensor provides a voltage during operation, wherein the voltage is a function of, in particular proportional to, a prevailing temperature.

The refinements and advantages explained in conjunction with the method are also analogously transferable to the converter/the sensor unit and between one another, and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows a converter that has multiple sensor units,

FIG. 2 shows an interconnection of the sensor units,

FIG. 3 shows a circuit diagram of one of the sensor units having an identical design,

FIG. 4 shows a method for determining the state of the converter,

FIG. 5 shows the temporal profile of a measured value, of a sensor value, and of a clock signal, and

FIG. 6 shows an example of the sensor unit according to FIG. 3.

### DETAILED DESCRIPTION

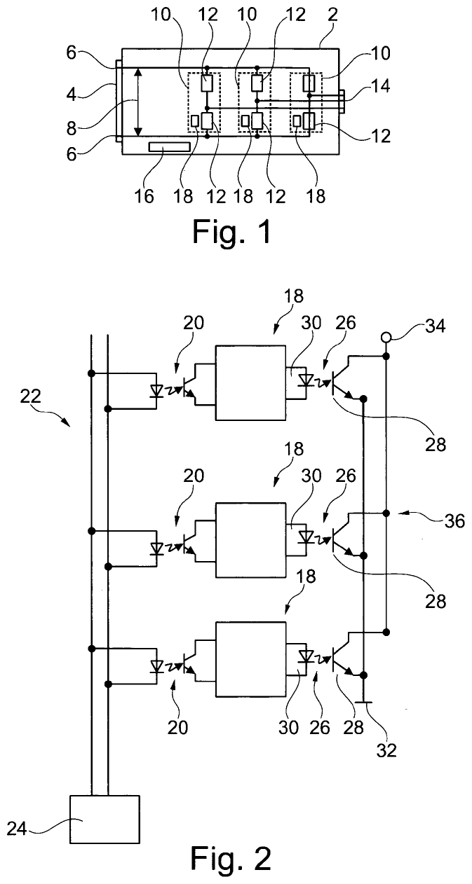

FIG. 1 shows a schematically simplified illustration of a converter 2 in the form of an inverter. The converter 2 has a direct voltage terminal 4 with two different terminals 6, between which a DC link voltage 8 of 400 V is present during operation. The two terminals 6 are electrically connected to one another via a module 10 in each case, the modules being electrically connected to one another in parallel between the terminals 6.

Each module 10 has two power semiconductor switches 12 electrically connected in series, so that a bridge branch is provided by means of each module 10, and the converter 2 has a bridge circuit, namely, a B6 circuit. A tap that is directed toward an alternating voltage terminal 14 of the converter 2 is formed between the power semiconductor switches 12 of each module 10. The power semiconductor switches 12 are actuated by means of a driver circuit, not illustrated in greater detail, which in turn is actuated by means of a controller 16, via which regulation of the converter 2 takes place as a function of external requirements. The controller 16 also monitors the operating parameters of the converter 2, which is switched off in the event of overheating, namely, when an operating temperature of the power semiconductor switches 12 exceeds a limit value such as 90° C.

The converter 2 has three sensor units 18 with the same design, each of the sensor units 18 being integrated into one of the respective modules 10. The sensor units 18 are in each case an integral part of a circuit board or a portion of a circuit board to which, for example, one or both power semiconductor switch(es) 12 is/are fastened. The sensor units 18 are spaced apart from one another.

FIG. 2 illustrates the interconnection of the sensor units 18. Each sensor unit 18 has a galvanic separator 20 in the form of a first optocoupler that is electrically contacted by a line 22 and that is operated by means of the line. In other words, the line 22 provides a signal on the basis of which the particular galvanic separator 20 is operated, so that the remainder of the sensor unit 18 is galvanically separated from the line 22. The galvanic separators 20 are electrically connected in parallel between two cores of the line 22. The line 22 is operated using a clock generator 24 that is an integral part of the controller 16.

Each sensor unit 18 also has a second optocoupler 26 which, the same as the first optocoupler, includes a switching element 28 that is operated by means of a light-emitting diode 30 of the second optocoupler 26. The switching elements 28 are electrically connected to one another in parallel, and are connected between a reference potential 32, namely ground, and an output point 34, for which purpose an output line 36 which thus includes two cores is used. In summary, the output line 36 is directed toward the output point 34, which is an integral part of the controller 16, which during operation queries the electrical potential present at the output point 34.

The output line 36 and the line 22 are implemented by a shared cable; due to the galvanic separator 20 and the second optocoupler 26, the lines and also the controller 16 are galvanically separated from the other electrical potentials for the remainder of the sensor units 18, and which are also directed by means of the modules 10. Requirements imposed on the cable and the controller 16 are thus reduced, even if portions of the sensor units 18 are not galvanically separated from the voltages that are directed by means of the power semiconductor switches 12.

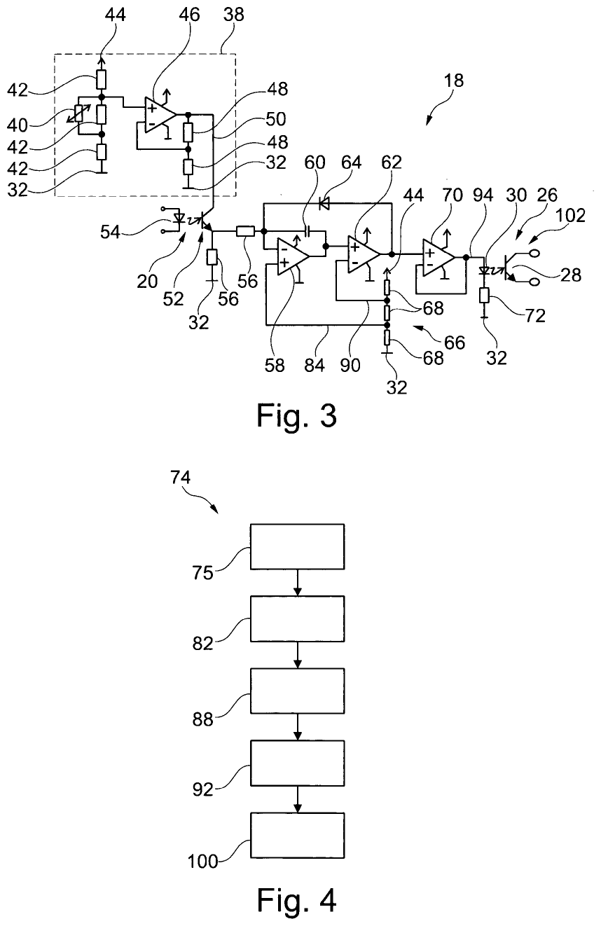

FIG. 3 illustrates a circuit diagram of one of the sensor units 18 having an identical design. Each sensor unit 18 has an analog sensor 38 that includes a temperature-dependent resistor 40 in each case. The temperature-dependent resistor is connected in parallel to the middle of three first auxiliary resistors 42 electrically connected in series, which are ohmic resistors and whose resistor values may differ. The series connection of the first auxiliary resistors 42 is established between two electrical potentials: in the example, between the reference potential 32 and an electrical auxiliary potential 44, which is predefined by a voltage source not illustrated in greater detail.

The non-inverting input of a further operational amplifier 46, which is connected to two second auxiliary resistors 48 to form a non-inverting amplifier circuit, is directed toward one of the terminals of the temperature-dependent resistor 40. For this purpose, the inverting input of the further operational amplifier 46 is directed toward the center tap of the electrical series connection of the second auxiliary resistors 48, which is directed between the output of the further operational amplifier 46 and the reference potential 32. Due to the interconnection, during operation a measured value 50 is present at the output of the further operational amplifier 46, namely, an electrical potential that is in a functional relationship with the present value of the electrical resistor of the temperature-dependent resistor 40, and thus with the temperature acting on same. The values of the auxiliary resistors 42, 48 are selected in such a way that essentially a linear amplification/conversion takes place in a temperature range between 60° C. and 100° C. Alternatively or in combination therewith, the values of the auxiliary resistors 42, 48 are selected in such a way that the change in the measured value 50 is as great as possible between 60° C. and 100° C. The measured value 50 is an analog value, so that the sensor is an analog sensor 38.

The output of the further operational amplifier 46 and thus the measured value 50 are directed toward the galvanic separator 20, namely, its associated switching element 52, which is electrically conductive when a voltage that is provided by means of the clock generator 24 is present at the light-emitting diode 54 of the galvanic separator 20. The switching element 52 in each case is directed toward two further resistors 56, one of which is directed toward the reference potential 32. The remaining further resistor 56 is directed toward the inverting input of a second operational amplifier 58, and is connected to the output of the second operational amplifier 58 via a capacitor 60. The output of the second operational amplifier 58 is also connected to the non-inverting input of a first operational amplifier 62, whose output is directed via a diode 64 toward the inverting input of the second operational amplifier 58.

Each sensor unit 18 also has a voltage divider 66 which includes three resistors 68 that are electrically connected in series, and which is connected between the reference potential 32 and the auxiliary potential 44. The non-inverting input of the second operational amplifier is directed toward one of the center taps of the voltage divider 66, and the inverting input of the first operational amplifier 20 is directed toward the remaining center tap.

The output of the first operational amplifier 62 is directed toward the non-inverting input of an additional operational amplifier 70, which is connected as a voltage follower. For this purpose, the output of the additional operational amplifier 70 is directed toward its inverting input. The output of the additional operational amplifier 70 is also directed toward the light-emitting diode 30 of the particular second optocoupler 26, which is turn is directed across an additional resistor 72 toward the reference potential 32. The values and designs of the further resistors 56, the resistors 68, and the additional resistor 72 may differ, and in particular are adapted to the particular operational amplifiers 58, 62, 70 used.

FIG. 4 illustrates a method 74 for determining the state of the converter 2, which is carried out using the sensor units 18 of the controller 16 and further components of the converter 2, such as the line 22 and the output line 36. The converter 2 is thus operated according to the method 74. In a first work step 75 a clock signal 76 is provided by means of the clock generator 24, and is sent to each of the sensor units 18 via the line 22.

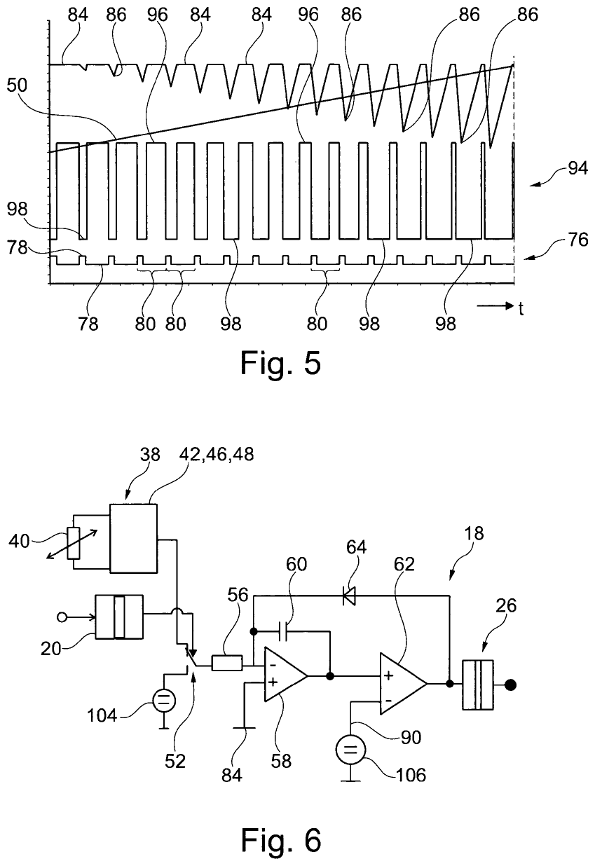

The clock signal 76, whose temporal profile is illustrated in FIG. 5, has two different clock states 78 between which the clock signal 76 alternates. The clock signal 76 is subdivided into identical successive clock pulses 80. Each clock pulse begins by assuming one of the clock states 78. Over the course of the particular clock pulse 80 it is changed to the other clock state 78, and the clock pulse 80 ends with a change back to the original clock state 78. The clock signal 76 is thus a binary signal, in particular a rectangular signal. The two clock states 78 are implemented using different electrical potentials.

The clock signal 76 is received essentially simultaneously by use of the galvanic separator 20 of each sensor unit 18, and is designed in such a way that upon receipt of the first clock state 78 of each clock pulse 80, the particular switching element 52 of the galvanic separator 20 is electrically conductive, so that the particular measured value 50 is sent to the second operational amplifier 58.

In the method, a second work step 82 is carried out in which a reference value 84, which is predefined and provided by means of the voltage divider 66, is reduced by the particular measured value 50 to a respective intermediate value 86 by negative integration, as also illustrated in FIG. 5. Thus, for the duration of one of the clock states 78, at the beginning of each clock pulse 80 the reference value 84 is reduced for as long as this clock state 78 continues. When this clock state 78 is ended, the particular intermediate value 86 is reached. With an increasing measured value 50, i.e., increasing temperatures, the particular intermediate value 56 is further reduced, and because the duration of these clock states 78 is always the same, the slope is steeper. In summary, for each sensor unit 18, during one of the clock states 78 of each clock pulse 80 the predefined reference value 84 is thus changed by the particular present measured value 50 to the respective intermediate value 86 by means of a predefined operation, namely, inverse integration. The time constant for the negative integration is determined based on one of the further resistors 56 and the capacitor 60. In particular, the first and second work steps 75, 82 are carried out simultaneously.

As soon as the clock signal 76 assumes the other clock state 78, a third work step 86 is carried out. In this work step the switching element 52 of the galvanic separator 20 no longer conducts current, so that initially no further operation of the second operational amplifier 58 takes place. However, by means of the first operational amplifier 62 the particular intermediate value 86 is changed by a respective auxiliary value 90 by means of the opposite operation, namely, integration, until the reference value 84 is once again reached. As soon as the reference value 84 has been reached, a further increase is prevented by the diode 64, so that the reference value 84 represents the maximum of the integration during each clock pulse 80.

In summary, in the method 74 negative integration is used as the operation for changing the reference value 84, and integration is used as the opposite operation for changing the intermediate value 86, for which purpose the two operational amplifiers 58, 62 are used. Due to the constant auxiliary value 90, the point in time at which the reference value 84 is reached in each case is a function of the intermediate value 86 and thus of the particular measured value 50. The point in time is also a function of the ratio of the reference value 84 to the particular auxiliary value 90, which is predefined by means of the voltage divider 66, since the reference value 84 and the auxiliary value 90 are provided by the shared voltage divider 66. However, the point in time is independent of the value of the auxiliary potential. Thus, by means of all sensor units 18, if the resistors 68 between the individual sensor units 18 have only low manufacturing tolerances, for the same measured value 50 the reference value 84 is always reached once again at the same point in time. In contrast, the other components of the sensor units 18 may be selected with comparatively high manufacturing tolerances, so that manufacturing costs of the sensor unit 18 are relatively low.

In a fourth work step 92, which is carried out essentially the same as for the second and third work steps 82, 88, a sensor value 94 is created by each sensor unit 18, for which purpose the additional operational amplifier 70 is also used. The particular sensor value 94, whose temporal profile is illustrated in FIG. 5, has a first state 96 and a second state 98, so that the sensor value 94 is binary. The first state 96 for the sensor value 94 is used after the reference value 84 has been reached once again in the particular clock pulse 80, and otherwise the second state 98 is used. The second state 98 is thus used during the integration and the negative integration. In summary, the sensor value 94 is thus synchronous with the clock pulses 80; however, the periods of time for which the different states 78, 96, 98 are assumed do not match one another, but for the sensor value 94 a change is made once between the two states 96, 98, during each clock pulse 80 and at its end.

With an increasing measured value 50, the time period for which the first state 96 is assumed during each clock pulse 80 is shortened, and at the beginning of each clock pulse 80 the sensor value 94 is the same as for the second state 98. In summary, for each of the sensor units 18 a corresponding sensor value 94 is thus present in each case, and these sensor values 94 are binary signals.

In a subsequent fifth work step 100, the particular sensor value 94 is fed into the output line 36 by means of each sensor unit 18, namely, a supply circuit 102 in each case which includes the respective second optocoupler 26. When the particular sensor value 94 has the second state 98, the light-emitting diode 30 of the particular second optocoupler 26 is activated in such a way that the switching element 28 of the second optocoupler 26 is electrically conductive. The particular sensor value 94 is thus transferred to the switching element 28 with galvanic separation. In summary, based on the particular sensor value 94, the switching element 28 of the particular supply circuit 102 of the respective sensor unit 18 is actuated. The fourth and fifth work steps 92, 100 preferably take place simultaneously.

In addition, the output point 34 is directed toward the reference potential 32 by means of the switching elements 28 of the second optocoupler 26, and this takes place for as long as at least one of the sensor values 94 has the second state 98. Consequently, the electrical potential is determined at the output point 34 only using the sensor value 94 for which the second state 98 is assumed for the longest time, the length thereof corresponding to the particular measured value 50.

In summary, only the sensor value 94 determines the electrical potential at the output point 34, which represents the maximum of all sensor values 94, i.e., an extreme value which namely corresponds to the highest measured value 50. As a result, only the extreme value of the sensor values 94, i.e., the highest temperature, is transferred to the output point 34. As long as this temperature is below a critical value such as 90°, the converter 2 is operated unchanged by means of the controller 16. In contrast, if the critical value is exceeded, overheating is assumed as the state of the converter 2, and the converter 2 is switched off or at least operated at reduced power. The state of the converter 2 is thus determined using the method 74.

FIG. 6 illustrates a modification of one of the sensor units 18, with the analog sensor 38 together with the temperature-dependent resistor 40 not being changed. The other components of the analog sensor 38, such as the further operational amplifier 46 and the auxiliary resistors 42, 48, are still present but not explicitly illustrated. The galvanic separator 20 is modified, and also continues to actuate the switching element 52, which, however, is not an integral part of the galvanic separator 20 but instead is separate therefrom. The switching element 52 is also connected to a further voltage source 104.

The interconnection of the first and second operational amplifiers 62, 58 to one of the further resistors 56, the capacitor 60, and the diode 64 is not changed. However, the reference value 84 is now provided via ground, and the auxiliary value 90 is provided via an additional voltage source 106. The further voltage source and additional voltage sources 104, 106 are direct voltage sources. The output of the first operational amplifier 62 is directed toward the second optocoupler 26, by means of which the switching element 28, not illustrated in greater detail, which is separate from the second optocoupler 26 is actuated.

The invention is not limited to the exemplary embodiments described above. Rather, other variants of the invention may also be derived by those skilled in the art without departing from the subject matter of the invention. In particular, all individual features described in conjunction with the individual exemplary embodiments may also be combined with one another in some other way without departing from the subject matter of the invention.

What is claimed is:

1. A method to determine a state of a converter based on at least two sensor values, each of which corresponds to a measured value that is created via an analog sensor of a particular sensor unit, the method comprising:
sending a clock signal comprising multiple identical clock pulses having two different clock states to each sensor unit;
changing, during one of the clock states of each clock pulse for each sensor unit, a predefined reference value by a present measured value to a respective intermediate value via a predefined operation;
changing, during another clock state of the respective same clock pulse for each sensor unit, a particular intermediate value by a respective auxiliary value up to a reference value via an opposite operation;
using, during the respective remaining time period of the same clock pulse, a first state as the particular sensor value and otherwise using a second state; and
providing the sensor values via a supply circuit into a shared output line that is directed toward an output point.

2. The method according to claim 1, wherein only an extreme value of the sensor values is transferred to the output point.

3. The method according to claim 2, wherein a switching element of the particular sensor unit, which is electrically connected in parallel between a reference potential and the output point, is actuated based on the particular sensor value.

4. The method according to claim 3, wherein the particular sensor value is transferred to the switching element with galvanic separation.

5. The method according to claim 1, wherein the clock signal is received via a galvanic separator of the particular sensor unit.

6. The method according to claim 1, wherein the reference value and the auxiliary value are provided by a shared voltage divider.

7. The method according to claim 1, wherein negative integration is used as the operation, and integration is used as the opposite operation.

8. A converter comprising at least two sensor units, each comprising an analog sensor, and an output line that is directed toward an output point, and that is operated according to the method according to claim 1.

9. The converter according to claim 8, wherein the converter is a power inverter that changes direct current to alternating current.
